(19) United States
(12) Patent Application Publication
(10) Pub. No.: US 2002/0137302 A1
(43) Pub. Date: Sep. 26, 2002

(54) Method of manufacturing semiconductor device

(75) Inventor: Sota Shinohara, Minato-ku (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/100,059

(22) Filed: Mar. 19, 2002

(30) Foreign Application Priority Data
Mar. 26, 2001 (JP) 2001-087554

(51) Int. Cl. H01L 21/76

(52) U.S. Cl. 438/400

(57) ABSTRACT

There is disclosed a method of manufacturing a semiconductor device to fabricate a capacitor structure while preventing a capacitor film from being peeled off, thereby increasing the yield and device reliability. The method comprises the steps of forming a laminated film made up of a close-contact film, a barrier film, and a close-contact film on a wafer, forming a metal film serving as a lower electrode on the laminated film radially inwardly, with respect to the wafer, of an outer edge of the laminated film, coating the metal film with a resist, etching a portion of the laminated film which is exposed radially outwardly, with respect to the wafer, from an outer edge of the metal, using the metal film as a mask, and after removing the resist from the metal film, forming a capacitor film in covering relation to the metal film.

### BACKGROUND OF THE INVENTION

1. Field of the Invention

The present invention relates to a method of manufacturing a semiconductor device, and more particularly to a method of manufacturing a ferroelectric memory.

2. Description of the Related Art

In dynamic random-access memories (DRAMs), one memory cell in a memory cell array comprises a cell transistor and a charge storage capacitor made of a dielectric film in the form of a thin SiO₂ (silicon oxide) film. Since the thin SiO₂ film has a small dielectric constant and cannot be highly integrated, research efforts have been directed in recent years to semiconductor memories having high-dielectric thin films or thin films of ferroelectric material as capacitor films.

Ferroelectric memories (FRAMs or Ferroelectric RAMs) utilize the polarization of a ferroelectrics film that once it is polarized under an electric field, the hysteresis thereof is maintained even when the power supply is turned off. Since a ferroelectric memory is capable of holding stored data, it operates as a nonvolatile memory.

Ferroelectric memories use capacitor films (capacitor insulating films) suitable for being highly integrated, in the form of thin films of ferroelectrics (hereinafter referred to as “ferroelectrics film”) such as Pb(Zr, Ti)O₃ (hereinafter referred to as “PZT”), (Pb, La) (Zr, Ti)O₃ (hereinafter referred to as “PZLT”) which is produced by adding La to PZT, SrBi₂Ta₂O₃ (hereinafter referred to a “SBT(Y1)”, etc. The ferroelectrics films have a specific inductive capacity of about 100.

The ferroelectrics film is sandwiched between lower and upper electrodes made of a metal having a weak affinity with oxygen such as a metal in the platinum group (noble metals), e.g., Pt, Ir, Ru, or the like, or an oxide of a metal in the platinum group, e.g., IrO₂, RuO₂, or the like.

The lower electrode, for example, of the ferroelectric memory is electrically connected via a contact to one of diffused layers (source and drain) of the cell transistor.

There is known a semiconductor device having a semiconductor substrate, at least one layer of metal interconnections (or a multilayer metal interconnection structure), and a capacitor, with a capacitor structure of a lower electrode, a capacitor film, and an upper electrode being formed upwardly of the metal interconnections. In such a semiconductor device, the layers below the metal interconnection layer can be manufactured by the same process as with ordinary LSI devices (see, for example, Japanese laid-open patent publication No. 11-317500). A process of manufacturing the lower electrode of the semiconductor device having the above capacitor structure will be described below.

FIGS. 1(a) and 1(b) of the accompanying drawings are views illustrative of a method of manufacturing the lower electrode of a conventional ferroelectric memory, the views schematically showing cross-sections along the diameter of a wafer upon fabrication of the lower electrode. In FIGS. 1(a) and 1(b), the opposite ends of the wafer correspond to the outer circumference of the wafer.

In FIG. 1(a), a cell transistor (diffused layers, a gate oxide film, a gate electrode, diffused layer contacts, etc), not shown, is formed on the surface of wafer 201. When a multilayer metal interconnection structure has been fabricated in an upper layer over wafer 201, a conductive close-contact film (Ti) and a conductive barrier film (TiN) are deposited by sputtering on uppermost interlayer insulating film (SiO₂) 202 on wafer 201, producing laminated film (TiN/Ti) 203 of the close-contact film and the barrier film on interlayer insulating film 202. Then, metal film 204 (e.g., Ru (ruthenium)) serving as a lower electrode is deposited by sputtering on laminated film 203 radially inwardly, with respect to the wafer, of the close-contact film (Ti). The barrier film, which is made of a conductive nitride such as TiN or the like, serves to prevent a mutual reaction and a mutual diffusion between W (tungsten) of the lower contact of the lower electrode and the metal film of the lower electrode.

When metal film (Ru) 204 serving as the lower electrode is grown, it is masked by a clamp ring of the sputtering apparatus, which is a ring for fixing the wafer to a stage used to place the wafer thereon and covers the outer circumferential edge of the wafer. In a wafer edge structure as shown in FIG. 1(a), therefore, metal film (Ru) 204 is formed radially inwardly, with respect to the wafer, of the outer edge of laminated film 203 of the barrier film and the close-contact film (TiN/Ti).

After a lower electrode structure which is made up of laminated film 203 of the barrier film and the close-contact film (TiN/Ti) and metal film (Ru) 204 is formed on insulating film 202, a thin ferroelectrics film such as of PZT or the like which serves as capacitor film 205 is deposited on the entire surface of the substrate by a CVD (MOCVD) process, i.e., a metal organic chemical vapor deposition process, as shown in FIG. 1(b), For forming a PZT film according to an ordinary sol-gel process or sputtering process, the assembly needs to be heated (annealed) at a temperature of 600° C. or higher to produce a good PZT film. However, the high-temperature treatment tends to cause disconnections in or increase the resistance of the metal interconnections of the multilayer metal interconnection structure that has already been formed beneath the lower electrode.

In the process of fabricating a semiconductor device having a capacitor structure on a multilayer metal interconnection structure, therefore, it is not preferable to grow a PZT film by sputtering or the like nor is it not practically feasible to grow a PZT film by sputtering or the like in view of the yield, reliability, and device properties.

For the fabrication of such a semiconductor device having a capacitor structure on a multilayer metal interconnection structure, a CVD process capable of producing a good thin PZT film in a temperature range from about 300 to 500° C. (substrate temperatures) is typically used to grow a thin PZT film.

A PZT film deposited on metal film (Ru) 204 as the lower electrode according to a CVD process is held in contact with the surface of laminated film 203 of the barrier film (TiN) and the close-contact film (Ti) which is located radially outwardly, with respect to the wafer, of the outer edge of metal film (Ru) 204 on the outer circumferential edge of the wafer (hereinafter referred to as “wafer edge”) (see FIG. 1(b)).

It has been confirmed on the fabrication line or by experimentation that when the PZT film is grown and annealed, if a PZT/TiN/SiO₂ structure or a PZT/TiN/Ti/SiO₂ structure is present as a laminated structure on the wafer edge, then the PZT film tends to be peeled off. Specifically, it has experimentally been confirmed that if the above laminated structure is present, then the grown PZT film comes off as powdery particles. In the step of forming the PZT film, the peeled-off powdery PZT particles are attached as foreign matter to the wafer surface, resulting in a reduction in the yield of ferroelectric memories.

As shown in FIG. 2 of the accompanying drawings, if metal film (Ru) 204 is deposited in covering relation to laminated film 203 of the barrier film (TiN) and the close-contact film (Ti) on the wafer edge, then a PZT/Ru/SiO₂ structure is present as a laminated structure on the wafer edge.

More specifically, metal film (Ru) 204 which is deposited in covering relation to laminated film 203 of the barrier film (TiN) and the close-contact film (Ti) is held in contact with the surface of insulating film (SiO₂) 202 radially outwardly, with respect to the wafer, of the outer edge of laminated film (TiN/Ti) 203, producing a step, and the laminated structure of PZT/Ru/SiO₂ is present on the wafer edge over the step when the PZT film is grown.

Experiments conducted by the inventor have confirmed that if the PZT/Ru/SiO₂ structure is present on the wafer edge when the PZT film is grown and annealed, then the films of PZT, Ru are peeled off. Therefore, the fabrication process shown in FIG. 2 is also liable to lower the yield of ferroelectric memories. One solution to the above problems is to align the edge of laminated film (TiN/Ti) 203 and the edge of metal film (Ru) 204 fully with each other to avoid the formation of a PZT/TiN/SiO₂ structure or a PZT/TiN/Ti/SiO₂ structure, or a PZT/Ru/SiO₂ structure on the wafer edge when the PZT film is annealed. However, it is difficult to carry out this process for the following reasons:

Since laminated film (TiN/Ti) 203 and metal film (Ru) 204 need to be grown in respective separate sputtering chambers, the area where laminated film (TiN/Ti) 203 is grown and the area where metal film (Ru) 204 is grown can easily be brought out of alignment with each other under different conditions even if the clamp rings used are designed in the same size. For aligning the edges of those areas fully with each other, it is necessary to control these film growing areas highly accurately in each of the sputtering chambers.

### SUMMARY OF THE INVENTION

It is therefore an object of the present invention to provide a method of manufacturing a semiconductor device to fabricate a capacitor structure while preventing a capacitor film from being peeled off, thereby increasing the yield and device reliability.

To achieve the above object, there is provided in accordance with the present invention a method of manufacturing a semiconductor device having a capacitor element, comprising the steps of forming a laminated film made up of a first close-contact film, a barrier film, and a second close-contact film arranged successively in the order named, on a wafer, forming a metal film serving as a lower electrode on the laminated film in a region radially inward, with respect to the wafer, of an outer edge of the laminated film, etching away a portion of the laminated film which is exposed radially outwardly, with respect to the wafer, of an outer edge of the metal film, and forming a capacitor film in covering relation to the metal film.

To accomplish the above object, there is also provided a method of manufacturing a semiconductor device having a capacitor element, comprising the steps of forming a laminated film made up of a first close-contact film, a barrier film, and a second close-contact film arranged successively in the order named, on a wafer, by forming the first close-contact film, forming the barrier film on the first close-contact film in a region radially inward, with respect to the wafer, of an outer edge of the first close-contact film, and then forming the second close-contact film in an area wider than the barrier film in covering relation to the barrier film, forming a metal film serving as a lower electrode on the second close-contact film in a region radially inward, with respect to the wafer, of outer edges of the first and second close-contact films, and forming a capacitor film in covering relation to the metal film.

The above and other objects, features, and advantages of the present invention will become apparent from the following description with reference to the accompanying drawings which illustrate examples of the present invention.

### BRIEF DESCRIPTION OF THE DRAWINGS

FIGS. 1(a) and 1(b) are cross-sectional views of a wafer edge structure manufactured by a conventional fabrication process;

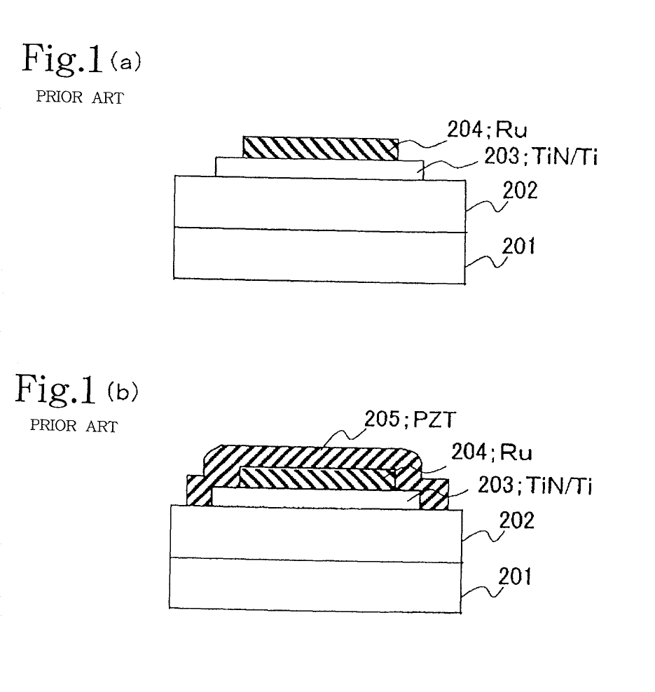

FIG. 2 is a cross-sectional view of a wafer edge structure manufactured by a conventional fabrication process;

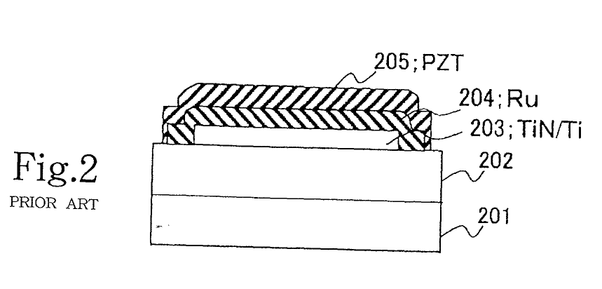

FIGS. 3(a) through 3(c) are cross-sectional views illustrative of a method of manufacturing a semiconductor device according to the present invention;

FIGS. 4(a) through 4(d) are cross-sectional views illustrative of a method of manufacturing a semiconductor device according to an embodiment of the present invention;

FIGS. 5(a) through 5(c) are fragmentary cross-sectional views illustrative of central steps of the method according to the embodiment of the present invention;

FIGS. 6(a) and 6(b) are fragmentary cross-sectional views of a device structure and a wafer edge structure in the fabrication of a ferroelectric memory by the method according to the embodiment of the present invention;

FIGS. 7(a) through 7(c) are fragmentary cross-sectional views of a device structure and a wafer edge structure in the fabrication of a ferroelectric memory by the method according to the embodiment of the present invention;

FIGS. 8(a) and 8(b) are fragmentary cross-sectional views of a device structure and a wafer edge structure in the fabrication of a ferroelectric memory by the method according to the embodiment of the present invention;

FIGS. 9(a) and 9(b) are fragmentary cross-sectional views of a device structure and a wafer edge structure in the fabrication of a ferroelectric memory by the method according to the embodiment of the present invention;

FIGS. 10(a) and 10(b) are fragmentary cross-sectional views of a device structure and a wafer edge structure in the fabrication of a ferroelectric memory by the method according to the embodiment of the present invention;

FIGS. 11(a) and 11(b) are fragmentary cross-sectional views of a device structure and a wafer edge structure in the fabrication of a ferroelectric memory by the method according to the embodiment of the present invention;

FIGS. 12(a) and 12(b) are fragmentary cross-sectional views of a device structure in the fabrication of a ferroelectric memory by the method according to the embodiment of the present invention;

FIG. 13 is a fragmentary cross-sectional view of a device structure in the fabrication of a ferroelectric memory by the method according to the embodiment of the present invention;

FIGS. 14(a) and 14(b) are fragmentary cross-sectional views of a device structure and a wafer edge structure in the fabrication of a ferroelectric memory by a method according to another embodiment of the present invention;

FIGS. 15(a) and 15(b) are fragmentary cross-sectional views of a device structure and a wafer edge structure in the fabrication of a ferroelectric memory by the method according to the other embodiment of the present invention;

FIGS. 16(a) and 16(b) are fragmentary cross-sectional views of a device structure and a wafer edge structure in the fabrication of a ferroelectric memory by the method according to the other embodiment of the present invention; and

FIGS. 17(a) and 17(b) are fragmentary cross-sectional views of a device structure and a wafer edge structure in the fabrication of a ferroelectric memory by the method according to the other embodiment of the present invention.

### DETAILED DESCRIPTION OF THE PREFERRED EMBODIMENTS

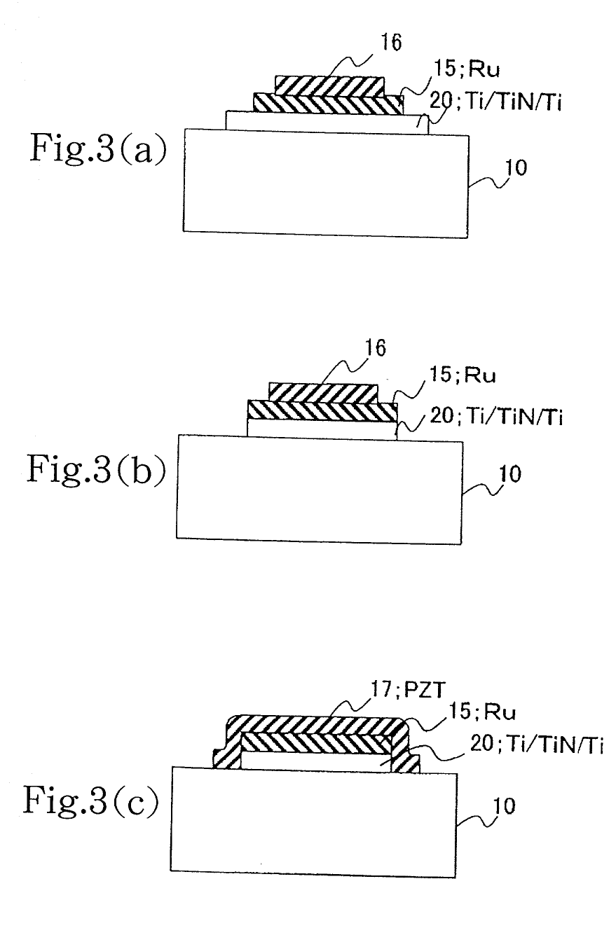

FIGS. 3(a) through 3(c) are cross-sectional views illustrative of a method of manufacturing a semiconductor device according to the present invention, the views being taken along the diameter of a wafer. In FIGS. 3(a) through 3(c), opposite ends of wafer 10 represent the outer circumference of wafer 10. In the method according to the present invention, as shown in FIG. 3(a), laminated film (e.g., Ti/TiN/Ti) 20 made up of a second close-contact film, a barrier film, and a first close-contact film is deposited on wafer 10, and metal film 15 serving as a lower electrode of a capacitor is formed on laminated film 20 radially inwardly, with respect to the wafer, of the outer edge thereof.

Then, as shown in FIG. 3(b), the upper surface of metal film 15 is coated with resist 16, and the edge portion of laminated film 20 which is exposed radially outwardly, with respect to the wafer, from the outer edge of the metal film (e.g., Ru) 15 is etched away.

Then, as shown in FIG. 3(c), resist 16 is removed, and thereafter capacitor film (e.g., PZT) 17 is deposited on the entire surface of the substrate in covering relation to metal film 15.

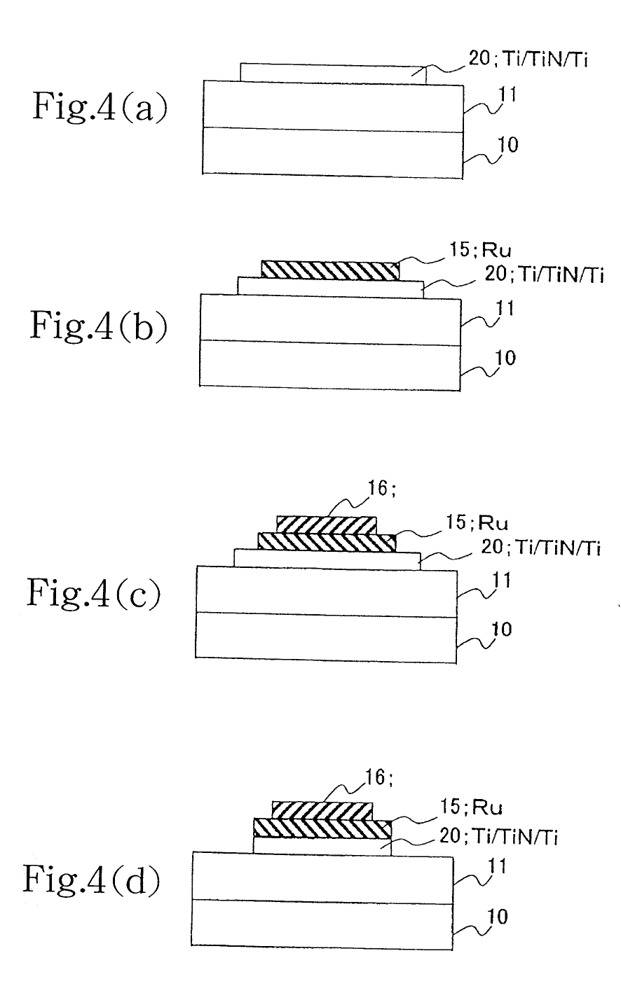

FIGS. 4(a) through 4(d) are cross-sectional views illustrative of a method of manufacturing a semiconductor device according to an embodiment of the present invention. A semiconductor memory device that is fabricated by the method according to the embodiment of the present invention has a multilayer metal interconnection structure on a silicon substrate, and a capacitor structure made up of a lower electrode, a capacitor film, and an upper electrode is formed above a predetermined one of the layers of the multilayer metal interconnection structure. The layers of the multilayer metal interconnection structure which are positioned beneath the predetermined layer are identical to those of an ordinary semiconductor memory device free of capacitor elements, and are manufactured by the same process as ordinary LSI devices.

For fabricating a lower electrode, as shown in FIG. 4(a), a first close-contact film (Ti), a barrier film (TiN), and a second close-contact film (Ti) are deposited successively in the order named on insulating film (interlayer insulating film) 11 on wafer 10, thus forming laminated film (Ti/TiN/Ti) 20. The first close-contact film (Ti), the barrier film (TiN), and the second close-contact film (Ti) are grown by sputtering, for example.

Then, as shown in FIG. 4(b), metal film 15 of a metal in the platinum group, e.g., Ru or the like, is grown as a lower electrode on the second close-contact film (Ti) radially inwardly, with respect to the wafer, of the outer edge of laminated film 20.

Then, as shown in FIG. 4(c), the upper surface of metal film (Ru) 15 is coated with resist 16.

Then, as shown in FIG. 4(d), using metal film (Ru) 15 as a mask, the outer portion of laminated film 20 which is exposed radially outwardly, with respect to the wafer, from the outer edge of the metal film (Ru) 15 is etched away. After the removal of the resist, a ferroelectrics film of PZT or the like is grown on the upper surface of metal film (Ru) 15 (see FIG. 3(c)).

In the method according to the embodiment of the present invention, if a ferroelectrics film of PZT or the like is used as a capacitor film, a laminated structure which comprises:

a capacitor film/a barrier film/an insulating film (PZT/TiN/SiO₂), and

a capacitor film/a barrier film/a close-contact film/an insulating film (PZT/TiN/Ti/SiO₂), is not present on the wafer edge.

Specifically, according to the embodiment of the present invention, a laminated structure present on the wafer edge comprises:

a capacitor film/an insulating film (PZT/SiO₂), and

a capacitor film/a metal film/a close-contact film/a barrier film/a close-contact film/an insulating film (PZT/Ru/Ti/TiN/Ti/SiO₂).

It has been experimentally confirmed that when the PZT film is formed in the semiconductor device having the above wafer edge, the PZT film is not peeled off.

According to a modification, when laminated film 20 made up of the first (lower) close-contact film, the barrier film, and the second (upper) close-contact film is formed in the step shown in FIG. 4(a), the barrier film may be formed such that its outer edge is positioned radially inwardly, with respect to the wafer, of the outer edge of the first close-contact film. In this case, the coating of the resist (FIG. 4(c)) and the etching process (FIG. 4(d)) are not required. The metal film serving as the lower electrode of the capacitor is formed such that the outer edge of the metal film is positioned radially inwardly, with respect to the wafer, of the outer edges of the first and second close-contact films, and then the capacitor film is formed in covering relation to the metal film. In the semiconductor device with the above wafer edge, the PZT film is not peeled off when it is formed.

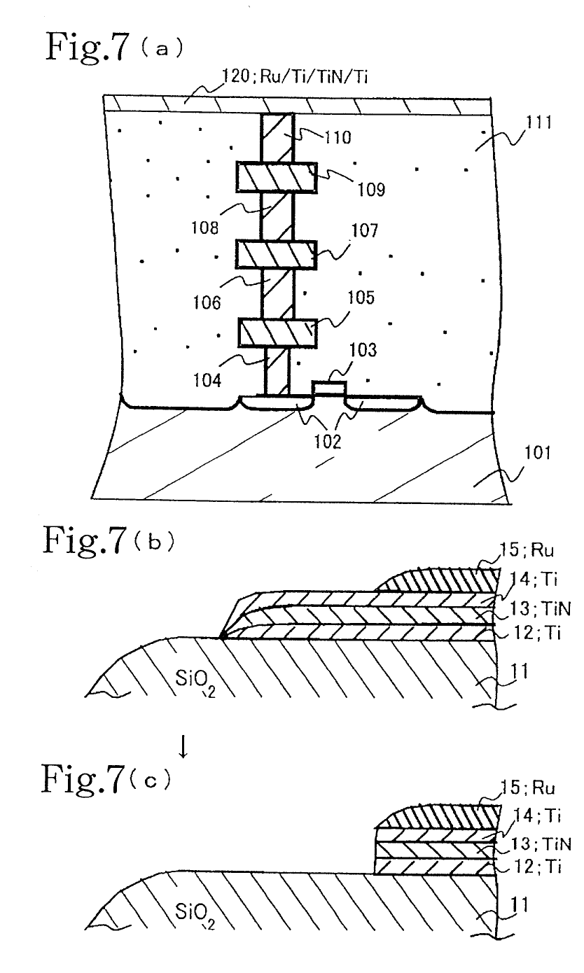

The first close-contact film, the barrier film, and the second close-contact film which are disposed between the lower electrode and the insulating film may be referred to as “barrier layer”. Of the three films, the uppermost second metal film serves to increase the close contact with the lower electrode. The metal nitride film formed beneath the second metal film is needed not only to inhibit the diffusion of a plug material and oxygen, but also to prevent the lower electrode from rising in a region above a plug (110 in FIG. 7(a)) of W (tungsten). The metal nitride film is required in view of the experimental fact that if the PZT film is formed on Ru/Ti, then the lower electrode tends to rise above the plug for the reason that the upward diffusion of the plug material has an effect on the rising of the lower electrode.

Simply laminating the first metal film and the metal nitride film is not sufficient to prevent the lower electrode from rising in the region above the plug in view of the experimental fact that if the PZT film is formed on Ru/Ti, then the lower electrode tends to rise above the plug.

To prevent the lower electrode from being peeled off, it is preferable to form a first metal film beneath the metal nitride film and to form a laminated film having at least three films including the first metal film, the metal nitride film, and the second metal film successively from below. The metal nitride film is preferably a nitride of the metal element of the first metal film or the second metal film.

The first metal film is required to prevent the lower electrode from being peeled off for the reason that the crystalline nature of the metal nitride film is affected by the crystalline nature of the film beneath the metal nitride film and the first metal film is effective to lessen a stress concentration on the plug.

Preferably, the three-layer film serving as the barrier layer comprises a three-layer film (Ti/TiN/Ti) having Ti films sandwiching a TiN film or a three-layer film (Ta/TaN/Ta) having Ta films sandwiching a TaN film because Ti and Ta are excellently held in close contact with Ir and Ru. Ti, TiN, Ta, and TaN are materials that are widely used in conventional LSI fabrication processes, and hence existing film growth facilities can be used to prevent the cost of semiconductor memories from increasing.

Preferably, the upper and lower electrodes of the ferroelectric (high-dielectric) capacitor are made chiefly of Ru or RuOx. Ru is only the material of the platinum group elements which can easily be processed in fine patterns by chemical etching.

The frequency with which the lower electrode rises strongly depends on the temperature at which the ferroelectric (high-dielectric) material is grown. Experiments conducted by the inventor show that if the temperature at which the PZT film is grown exceeds 475° C., then the lower electrode may occasionally rise even if a three-layer film is used as a barrier film. Therefore, the ferroelectric (high-dielectric) material should be grown preferably at a temperature of 500° C. or lower, or more preferably at a temperature of 475° C. or lower.

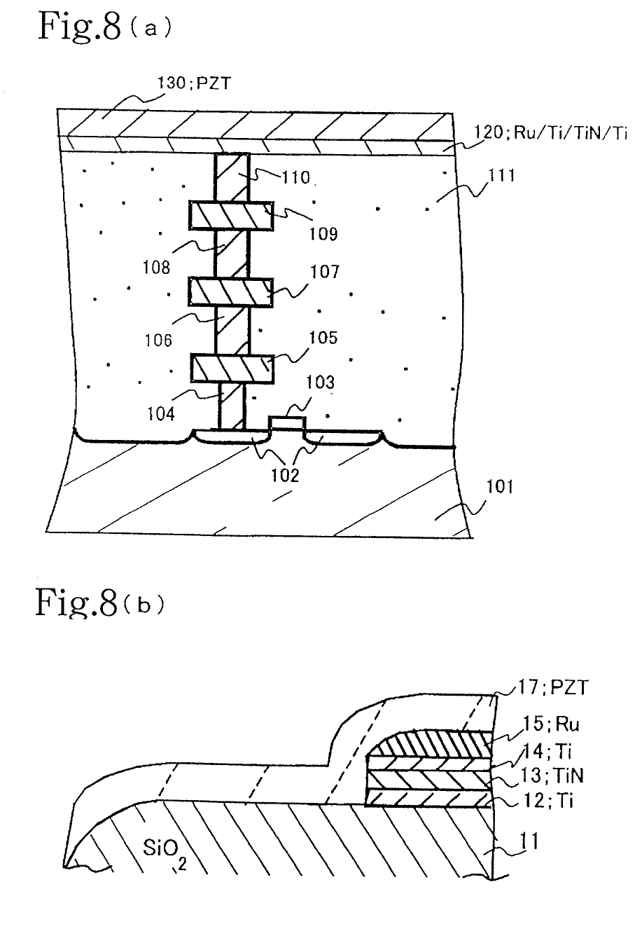

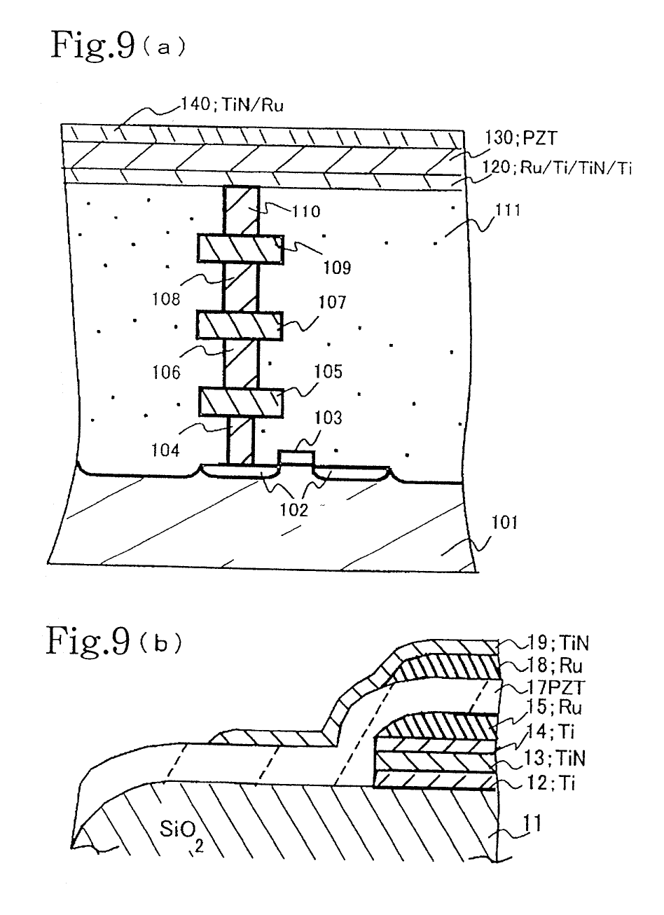

According to the embodiment of the present invention, as described above, the barrier layer includes at least three films, i.e., a first metal film (12 in FIG. 9(b)), a metal nitride film (13 in FIG. 9(b)), and a second metal film (14 in FIG. 9(b)) successively from below. According to the present invention, there is provided a method of manufacturing a semiconductor device having a capacitor element disposed on a semiconductor substrate and having a lower electrode (15 in FIG. 9(b)) and an upper electrode (18 in FIG. 9(b)) which sandwich a dielectric film (17 in FIG. 9(b)), and a barrier layer disposed between the capacitor element and an insulating film beneath the lower electrode, the semiconductor device being electrically connected to a base layer (107, 105, 102 in FIG. 9(a)) by a conductive member (plug 110 in FIG. 9(a)) disposed in insulating film (111 in FIG. 9(a)), the method comprising the steps of forming a laminated film made up of the first metal film (12 in FIG. 7(b)) serving as the barrier layer, the metal nitride film (13 in FIG. 7(b)), and the second metal film (14 in FIG. 7(b)) successively on the insulating film (11 in FIG. 7(b)) on a wafer, forming a metal film serving as the lower electrode (15 in FIG. 7(b)) on the laminated film in a region radially inward, with respect to the wafer, of the outer edge of the laminated film, etching away (FIG. 7(c)) an edge portion of the laminated film which is exposed radially outwardly, with respect to the wafer, from the outer edge of the metal film as the lower electrode, and forming a dielectric film (17 in FIG. 8(b)) in covering relation to the metal film (15 in FIG. 8(b)) as the lower electrode. The metal nitride film (13 in FIG. 7(b)) is made of a nitride of the metal element of the second metal film (14 in FIG. 7(b)). The manufacturing method is effective to prevent the lower electrode from rising in the region above the plug while the capacitor film is being grown or subsequently annealed, and to prevent the PZT film from being peeled off on the wafer edge when the PZT film is grown.

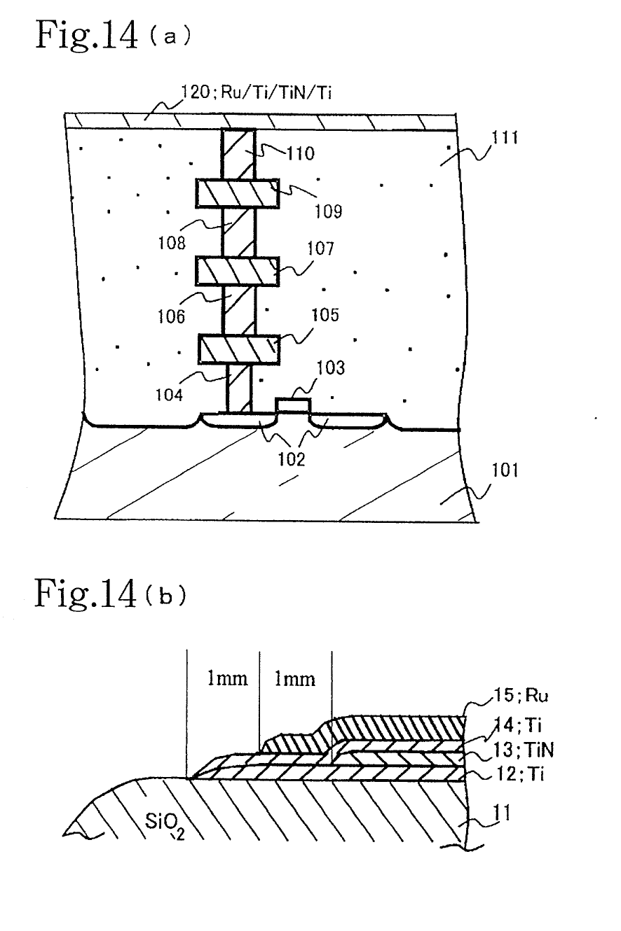

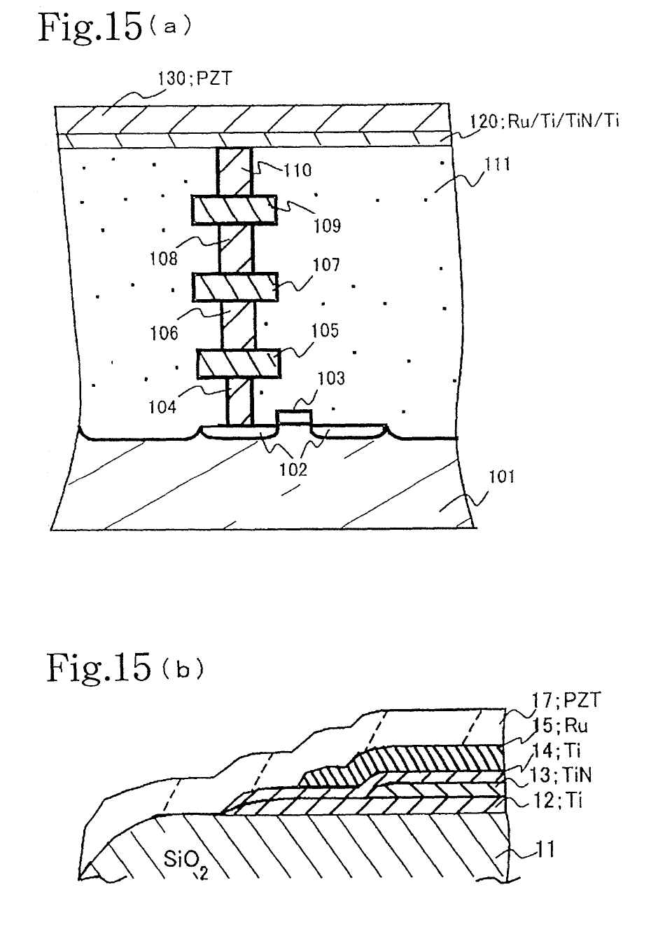

According to the embodiment of the present invention, alternatively, the method comprises the step of forming the laminated film serving as the barrier layer and made up of the first metal film (12 in FIG. 14(b)), the metal nitride film (13 in FIG. 14(b)), and the second metal film (14 in FIG. 14(b)) successively on the insulating film (11 in FIG. 14(b)) on the wafer, the step comprising the steps of forming the first metal film (12 in FIG. 14(b)), forming the metal nitride film (13 in FIG. 14(b)) on the first metal film in a region radially inward, with respect to the wafer, of the outer edge of the first metal film, and forming the second metal film (14 in FIG. 14(b)) in covering relation to the metal nitride film (13 in FIG. 14(b)) in an area wider than the metal nitride film, the method further comprising the steps of forming a metal film (15 in FIG. 14(b)) as the lower electrode in a region radially inward, with respect to the wafer, of the outer edges of the first and second metal films, and forming a dielectric film (17 in FIG. 15(b)) in covering relation to the metal film (15 in FIG. 15(b)) as the lower electrode. In this embodiment, the metal film (15 in FIG. 14(b)) as the lower electrode extends to a region radially outward, with respect to the wafer, of the outer edge of the metal nitride film (13 in FIG. 14(b)). The metal nitride film (13 in FIG. 14(b)) is made of a nitride of the metal element of the first metal film (12 in FIG. 14(b)) or the second metal film (14 in FIG. 14(b)). The PZT film is prevented from being peeled off on the wafer edge when the PZT film is grown.

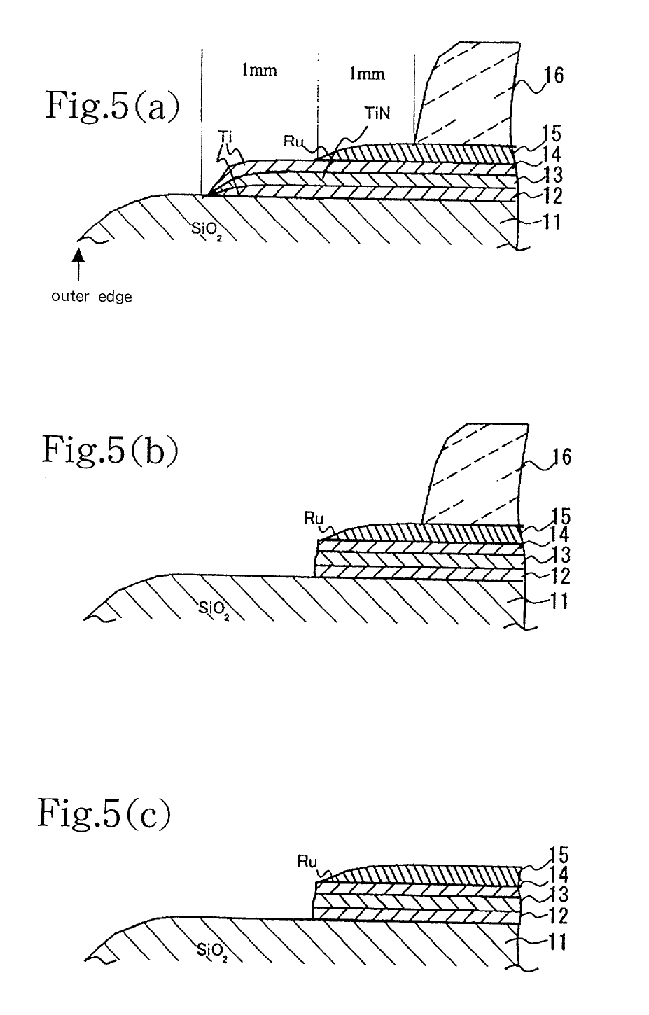

The embodiment of the present invention will be described in greater detail below with reference to the drawings. FIGS. 5(a) through 5(c) show successive steps of the manufacturing method according to the embodiment of the present invention, and illustrate cross-sectional structures of the outer circumferential edge of the wafer (wafer edge structures). In FIGS. 5(a) through 5(c), the left-hand side corresponds to the outer edge of the wafer, and the left-hand side to the radially inner side of the wafer.

As shown in FIG. 5(a), first close-contact film (Ti) 12, barrier film (TiN) 13, and second close-contact film (Ti) 14 are grown successively in the order named on insulating film (SiO₂) on a wafer, and metal film (Ru) 15 serving as a lower electrode is grown on the surface formed so far radially inwardly, with respect to the wafer, of the laminated film of the second close-contact film, the barrier film, and the first close-contact film (Ti/TiN/Ti) on the wafer edge. The positional relationship between the outer edges of these films is appropriately adjusted by the clamp ring of the sputtering apparatus when the Ru, Ti, TiN films are grown. In the example shown in FIG. 5(a), the outer edge of metal film (Ru) 15 is positioned 1 mm radially inwardly, with respect to the wafer, of the outer edge of the laminated film.

Resist 16 is placed on metal film (Ru) 15 as the lower electrode radially inwardly, with respect to the wafer, of the outer edge of metal film (Ru) 15. Specifically, the wafer is coated with resist 16, and then the wafer edge is rinsed by an organic solvent such as propanol or the like, thus adjusting the position of the outer edge of resist 16. In the example shown in FIG. 5(a), the outer edge of resist 16 is positioned about 1 mm radially inwardly, with respect to the wafer, of the outer edge of metal film (Ru) 15.

Then, the wafer is dipped for about 4 minutes in a solution at about 70° C. of a mixture of ammonia: 40%, hydrogen peroxide water, and pure water at a ratio of 1:4:20 (weight ratio), thus wet-etching Ti/TiN/Ti. As shown in FIG. 5(b), with Ti/TiN/Ti thus etched, the radial direction of the outer edge of the laminated film of Ti/TiN/Ti is held in alignment with the outer edge of metal film (Ru) 15.

In the wet-etching process, the Ru of lower electrode 15 is substantially not etched, but slightly modified and would be responsible for impairing the subsequent growth of a PZT film. According to the present embodiment, the surface of metal film (Ru) 15, and hence most of the wafer surface, is covered with resist 16. The process of etching the laminated film of Ti/TiN/Ti is aimed at etching the wafer edge, and employs isotropic wet etching as it does not require anisotropic etching. However, dry etching may be employed in the process of etching the laminated film of Ti/TiN/Ti.

Thereafter, as shown in FIG. 5(c), the resist (16 in FIG. 5(b)) is removed by an organic solvent such as methyl ethyl ketone.

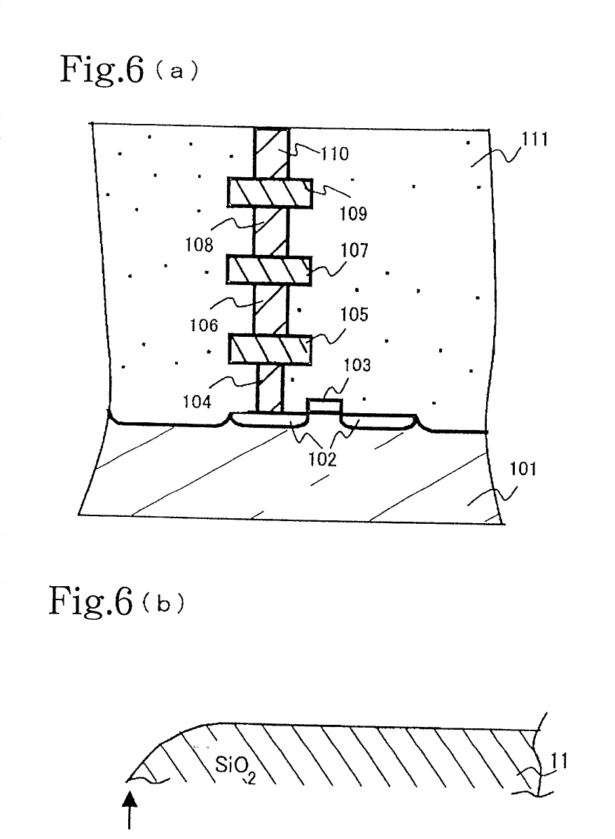

A method of manufacturing a ferroelectric memory according to the embodiment of the present invention will be described below. FIGS. 6(a) through 13 show a device structure and a corresponding wafer edge structure, when necessary, on a silicon substrate (wafer) in respective typical fabrication steps of the method. Subsequent to the step where the wafer edge structure remains unchanged, a wafer edge structure is not illustrated, but only a device structure is shown.

As shown in FIG. 6(a), a memory cell transistor and a multilayer metal interconnection structure are formed on a silicon substrate (wafer) according to an LSI fabrication process. FIG. 6(a) shows a device structure including third metal interconnection layer 109, interlayer insulating layer 111 formed over third metal interconnection layer 109 and having a via hole defined in a surface thereof, and fourth plug (via plug) 110 of W (tungsten) or the like formed in the via hole. In FIG. 6(a), the multilayer metal interconnection structure has diffused layers 102 serving as the source and drain of the memory cell transistor and formed in the surface of silicon substrate 101, a gain oxide film and gate electrode 103, first plug 104 held in contact with one of the diffused layers, first metal interconnection 105 disposed on first plug 104, second plug 106 connected to first metal interconnection 105, second metal interconnection 107, third plug 108 connected to second metal interconnection 107, third metal interconnection 109, fourth plug 110 connected to third metal interconnection 109, and interlayer insulating films. Fourth plug 110 is electrically connected to the lower electrode of a capacitor structure which is formed in steps described below.

FIG. 6(b) shows a wafer edge structure corresponding to the fabrication step shown in FIG. 6(a). The wafer edge is covered with insulating film (SiO₂) 11. On the wafer edge, the uppermost layer of insulating film (SiO₂) 11 is an interlayer insulating film in the uppermost layer of the device structure.

In the device structure shown in FIG. 6(a), the materials of first through third metal interconnections 105, 107, 109 include TiN, AlCu, TiN, and Ti and have respective thicknesses of 30 nm, 800 nm, 30 nm, and 20 nm. The metal interconnections are grown by sputtering, and the temperature of the substrate at the time the metal interconnections are grown is typically about 300° C. The materials of the metal interconnections may be Cu, TaN, metal silicide, metal nitride, etc. other than the above materials. The metal interconnections may be grown by CVD, evaporation, or the like other than sputtering. First through fourth plugs 104, 106, 108, 110 comprise W (tungsten) plugs, have a height of about 800 nm, and are grown by CVD while the substrate is kept at a temperature of about 400° C. The material of the plugs is not limited to W, but may be polycrystalline silicon or copper.

Then, as shown in FIG. 7(a), a laminated film made up of a lower electrode, a close-contact film, a barrier film, and a close-contact film (Ru/Ti/TiN/Ti) is grown on insulating film 111 on the substrate.

In the present embodiment, upon the growth of the laminated film of Ru/Ti/TiN/Ti in a wafer edge structure shown in FIG. 7(b), a Ti film serving as each of lower and upper close-contact films 12, 14 has a thickness of 20 nm and is grown by sputtering while the substrate is kept at a typical temperature of about 300° C. A TiN film serving as barrier film 13 has a thickness of 50 nm and is grown by sputtering while the substrate is kept at a typical temperature of about 300° C. The Ru film serving as metal film 15 of the lower electrode has a thickness of 100 nm and is grown by sputtering while the substrate is kept at a typical temperature of about 300° C.

Using metal film (Ru) 15 as a mask, the laminated film of Ti/TiN/Ti on the wafer edge is etched. Resist 16 (applied to metal film (Ru) 15) is omitted from illustration in FIG. 7(b). As a result, in the wafer edge structure shown in FIG. 7(c), the edge portion of the laminated film of Ti/TiN/Ti which is exposed radially outwardly, with respect to the wafer, from the outer edge of metal film (Ru) 15 is removed, and the etched outer edge of the laminated film of Ti/TiN/Ti and the outer edge of metal film (Ru) 15 are aligned with each other in the radial direction of the wafer.

Then, as shown in FIG. 8(a), PZT film 130 is grown on the entire surface formed so far. In the present embodiment, PZT film 130 is grown to a thickness of 250 nm by CVD while the substrate is kept at a temperature of about 430° C. For the material of PZT film 130, reference should be made to the description of Japanese laid-open patent publication No. 11-317500, for example. Then, PZT film 130 is annealed at about 400° C. in an oxygen atmosphere. At this time, the wafer edge is of a structure as shown in FIG. 8(b) where PZT film 17 is formed on Ru film 15 and insulating film (SiO₂) 11 and held in contact with a side wall of the laminated film of Ru/Ti/TiN/Ti.

As described above, if a laminated structure of PZT/Ru/SiO₂ or PZT/TiN/SiO₂ is present on the wafer edge when the PZT film is grown and annealed, then the PZT film is peeled off, producing particles which tend to lower the yield of ferroelectric memories.

According to the present embodiment, as shown in FIG. 8(b), a laminated structure present on the wafer edge is composed of only:

PZT/SiO₂, and

PZT/Ru/Ti/TiN/Ti/SiO₂,

and no laminated structure of PZT/Ru/SiO₂ and PZT/TiN/SiO₂ is present on the wafer edge. Consequently, the PZT film is prevented from being peeled off when the PZT film is grown and annealed.

Then, as shown in FIG. 9(a), a laminated film (TiN/Ru) 140 of Ru serving as the upper electrode and TiN serving as a cap layer is deposited on PZT film 130. Specifically, after an Ru film is deposited as metal film 18 of the upper electrode, a TiN film is deposited as upper electrode cap layer 19 on the Ru film. The metal film Ru as the upper electrode is eliminated by an oxygen plasma process after the subsequent formation of a contact. The oxygen plasma process is a process for removing a photosensitive resist used in processing the capacitor element and forming a contact with the upper electrode. The cap layer of TiN deposited on the upper electrode serves as a protective film for protecting the metal film Ru against elimination in the oxygen plasma process. As shown in FIG. 9(b) which illustrates a wafer edge structure corresponding to the fabrication step shown in FIG. 9(a), the Ru film as the metal film 18 of the upper electrode is grown to a thickness of 100 nm by sputtering as is the case with metal film 15 of the lower electrode. Upper electrode cap layer (TiN) 19 is grown to a thickness of 60 nm by sputtering while the substrate is kept at a temperature of 300° C. The material of upper electrode cap layer 19 is not limited to TiN, but may be a metal other than Ru of the metal film of the upper electrode. Upper electrode cap layer may be grown by CVD, evaporation, or the like other than sputtering.

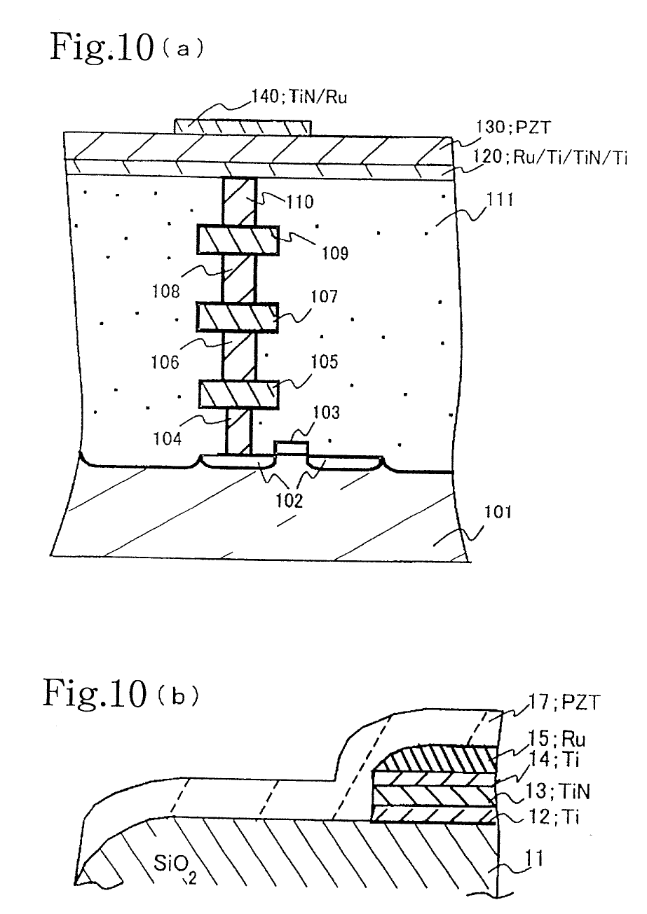

Thereafter, as shown in FIG. 10(a), the laminated film (TiN/Ru) of the upper electrode and the upper electrode cap layer is patterned to an electrode pattern. In a wafer edge structure corresponding to this fabrication step as shown in FIG. 10(b), the laminated film (TiN/Ru) of the upper electrode and the upper electrode cap layer is removed at the outer circumferential edge of the wafer by the etching of TiN/Ru for the formation of the electrode pattern, exposing the surface of PZT film 17.

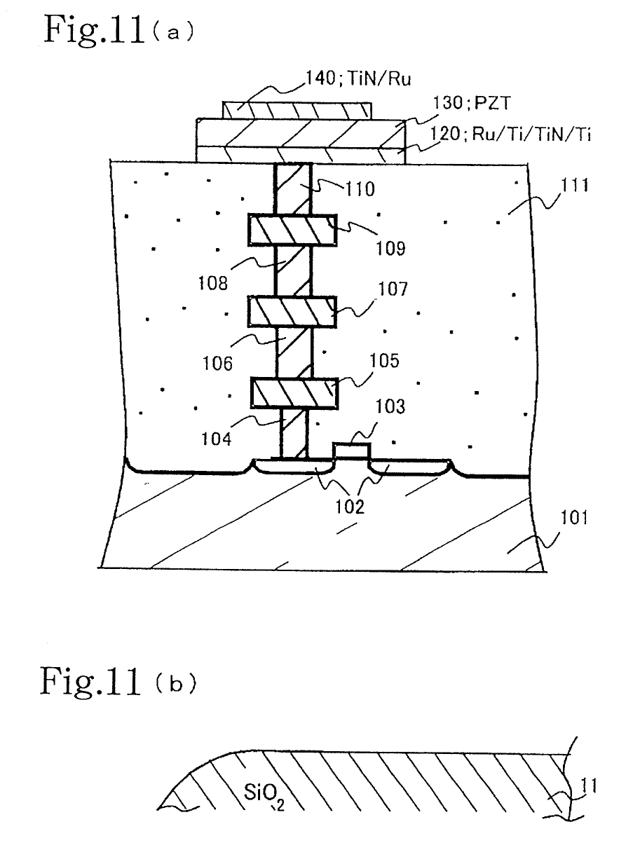

Then, as shown in FIG. 11(a), the laminated film PZT/Ru/Ti/TiN/Ti of the capacitor film and the lower electrode structure is patterned to a capacitor structure of the device. In a wafer edge structure shown in FIG. 11(b), the laminated film PZT/Ru/Ti/TiN/Ti is removed, exposing insulating film SiO₂. In subsequent steps, the wafer edge structure is composed of the insulating film only, as shown in FIG. 11(b), and the wafer edge structure in each of those steps is omitted from illustration.

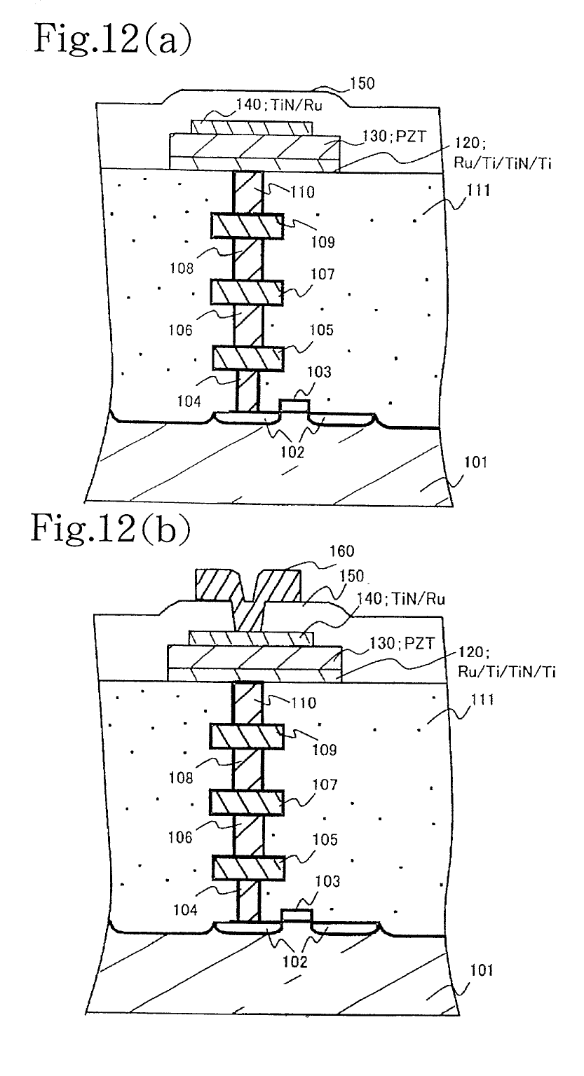

Then, as shown in FIG. 12(a), capacitor cover film 150 is formed. In the present embodiment, capacitor cover film 150 is of a thickness of 500 nm. Capacitor cover film (SiO₂) 150 is grown by TEOS (tetra ethyl orthosilicate) CVD while the substrate is kept at a temperature of 375° C. However, capacitor cover film 150 may be formed of SiH₄, N₂O by plasma CVD. Thus, the material of capacitor cover film 150 is not limited to SiO₂, but may be SiON, SiN, or the like.

Then, as shown in FIG. 12(b), a contact hole is formed by etching, and plate line 160 for connecting to upper electrode 140 is formed. In the present embodiment, the materials of plate line 160 include TiN, AlCu, TiN, and Ti and have respective thicknesses of 20 nm, 300 nm, 50 nm, and 20 nm. The plate line may be made of copper, TaN, metal silicide (high-melting-point metal silicide), metal nitride, or the like.

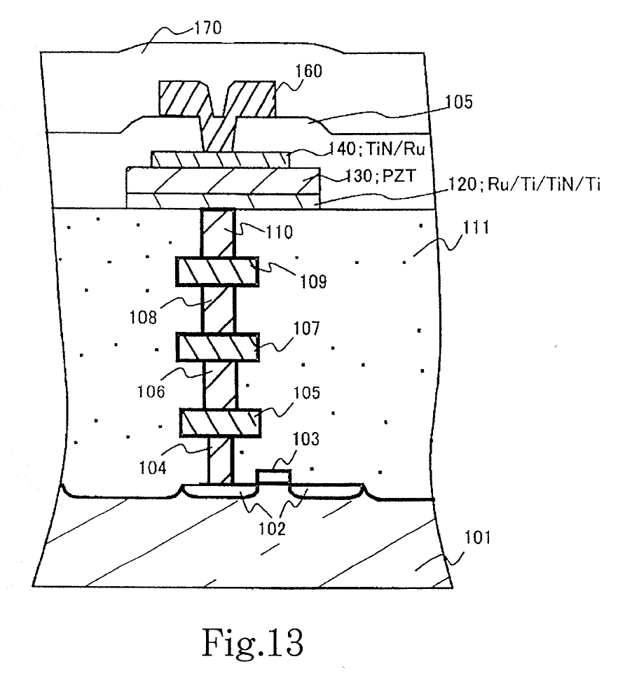

Thereafter, as shown in FIG. 13, passivation film 170 is formed. In the present embodiment, passivation film 170 comprises a film of SiO₂ having a thickness of 100 nm and a film of SiON having a thickness of 1000 nm on the film of SiO₂. Passivation film 170 is formed of SiH₄, N₂O, and NH₃ by plasma CVD while the substrate is kept at a temperature of 300° C. However, passivation film 170 may be grown by CVD, evaporation, or the like.

As described above, the present embodiment is preferably applicable to a method of manufacturing a semiconductor device by forming a metal interconnection layer and thereafter forming a capacitor structure, and serves to increase the yield of products, without the danger of the capacitor film being peeled off.

A second embodiment of the present invention will be described below. According to the second embodiment of the present invention, the positions of a close-contact film, a barrier film, a lower electrode metal film are adjusted by the clamp ring of the sputtering apparatus, and the step of etching the laminated film made up of the close-contact film, the barrier film, and the close-contact film (Ti/TiN/Ti) according to the previous embodiment is dispensed with.

According to the second embodiment of the present invention, specifically, for growing a laminated film made up of a lower electrode metal film, a second close-contact film, a barrier film, and a first close-contact film, the size (inside diameter) of the clamp ring of the sputtering apparatus is adjusted, and the first and second close-contact films, the lower electrode metal film, and the barrier film are grown so as to be positioned successively radially inwardly, with respect to the wafer, of the wafer, followed by the growth of a PZT film as a capacitor film. Reference should be made to Japanese laid-open patent publication No. 11-29769, for example, for a method of using, as a mask, a clamp ring for fixing the outer circumferential edge of a semiconductor wafer to a stage and changing an area where a film is to be grown thereby to prevent the film from being peeled off. This publication proposes a process in which after a TiN film is grown on a semiconductor wafer except for its outer circumferential edge, a CU seed film is grown in covering relation to the TiN film to prevent the TiN film from being exposed even when the TiN film and the Cu seed film are positionally misaligned when they are grown, and a Cu plated film grown on the Cu seed film is prevented from being peeled off on the TiN film.

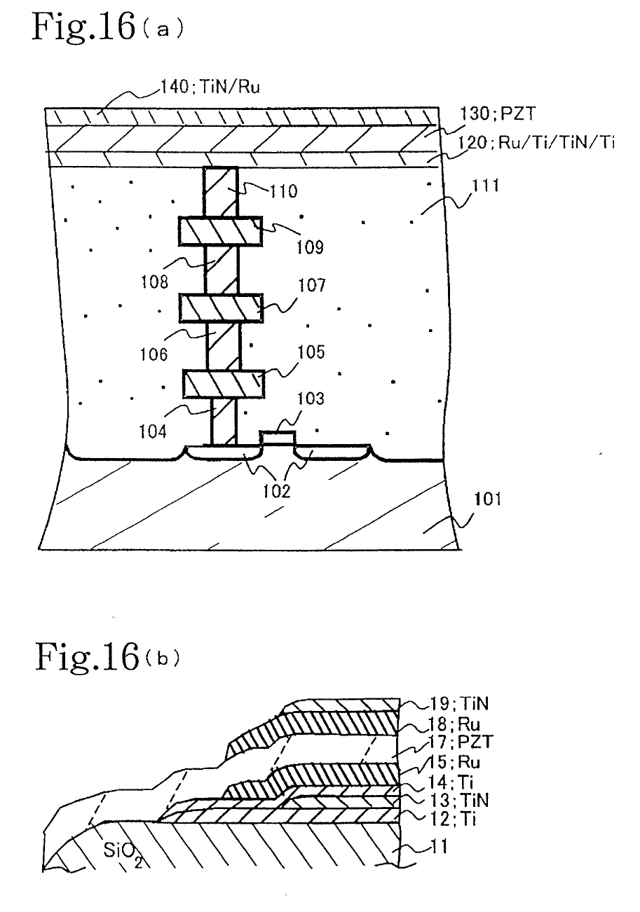

A method of manufacturing a ferroelectric memory according to the second embodiment of the present invention will be described below. FIGS. 14(a) through 17(b) show a device structure and a corresponding wafer edge structure in respective fabrication steps of the method. The manufacturing method according to the second embodiment of the present invention will be described below with reference to FIGS. 14(a) through 17(b) and FIGS. 6(a) through 11 which have been referred to in the previous embodiment.

A device structure and a wafer edge structure in the first step for producing a capacitor structure according to the second embodiment are identical to those shown in FIGS. 6(a), 6(b), and will not be described below.

Following the step shown in FIGS. 6(a), 6(b), as shown in FIG. 14(a), laminated film 120 of Ru/Ti/TiN/Ti serving as a lower electrode structure is grown on interlayer insulating layer (SiO₂) 111. Specifically, as shown in FIG. 14(b), a Ti film serving as lower close-contact film 12 is grown on insulating film (SiO₂) 11 by a sputtering apparatus. Then, a TiN film serving as barrier film 13 is grown on the Ti film radially inwardly, with respect to the wafer, of the outer edge of the Ti film (by a distance of 2 mm in the example shown in FIG. 14(b)). For growing the TiN film, a ring having a diameter (opening diameter) smaller than a ring used to grow the Ti film is used as the clamp ring of the sputtering apparatus.

Then, a Ti film serving as upper close-contact film 14 is grown on the TiN film radially outwardly, with respect to the wafer, of the outer edge of the TiN film. In the example shown in FIG. 14(b), a clamp ring used to grow the TiN film as upper close-contact film 14 has the same diameter as the clamp ring used to grow the Ti film as lower close-contact film 12, and the TiN film as upper close-contact film 14 covers the outer edge of the TiN film serving as barrier film 13 and has its outer edge aligned with the outer edge of the Ti film as lower close-contact film 12. Then, an Ru film serving as lower electrode metal film 15 is grown such that its outer edge is positioned radially inwardly, with respect to the wafer, of the outer edge of the Ti film as the close-contact film by a distance of about 1 mm. For growing the Ru film, a ring having a diameter (opening diameter) smaller than the ring used to grow the Ti film and larger than the ring used to grow the TiN film is used as the clamp ring of the sputtering apparatus. According to this manufacturing method, no etching step is required.

Then, as shown in FIG. 15(a), PZT film 130 is grown and then annealed. As shown in FIG. 15(b), when the PZT film is grown and annealed, a wafer edge structure composed of:

PZT/SiO₂,

PZT/Ti(two layers)/SiO₂,

PZT/Ru/Ti(two layers)/SiO₂, and

PZT/Ru/TiN/Ti/SiO₂

which are arranged successively from the outer circumferential edge, is present. According to the second embodiment of the present invention, when the PZT film is grown and annealed, a structure of PZT/Ru/SiO₂, PZT/TiN/SiO₂ is not present. Therefore, the films of PZT, Ru, etc., are prevented from being peeled off.

Then, as shown in FIGS. 15(a), 15(b), an Ru film serving as upper electrode metal film 18 is grown to a thickness of 100 nm by sputtering, and a TiN film serving as upper electrode cap layer 19 is grown on the Ru film. As described above, the TiN film as upper electrode cap layer 19 serves as a protective film for protecting the Ru film against elimination in the oxygen plasma process after the subsequent formation of a contact.

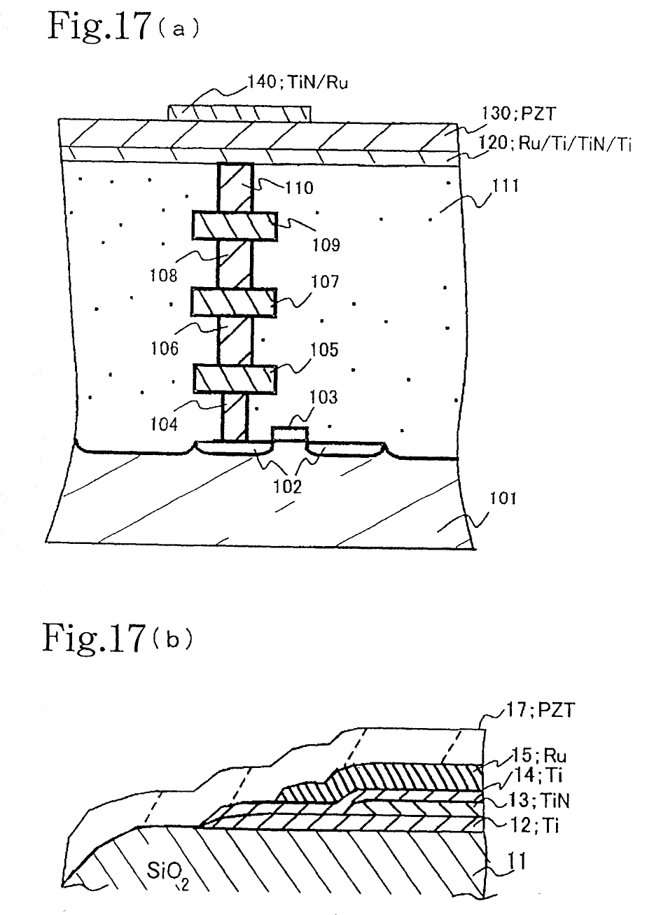

Thereafter, as shown in FIG. 17(a), laminated film (TiN/Ru) 140 is patterned to an electrode pattern by etching. As shown in FIG. 17(b), a wafer edge structure obtained at this time has a film of TiN/Ru removed and PZT film 17 exposed.

Then, as shown in FIG. 11(a), the laminated film PZT/Ru/Ti/TiN/Ti is patterned by etching. In a resultant wafer edge structure, as shown in FIG. 11(b), the insulating film is exposed. In subsequent steps, the wafer edge structure remains the same.

The steps of forming a capacitor cover film, a plate line, and a passivation film are the same as those of the previous embodiment described above with reference to FIGS. 11(a) through 12(b), and will not be described below.

The second embodiment of the present invention is also preferably applicable to a method of manufacturing a semiconductor device, which has the steps of forming a metal interconnection layer and thereafter forming a ferroelectric capacitor film. With the second embodiment, when the PZT film is grown and annealed, a wafer edge structure composed of PZT/Ru/SiO₂, PZT/TiN/SiO₂ is not present on the wafer edge. Therefore, the films of PZT, Ru, etc. are prevented from being peeled off, and the yield of products is increased.

In each of the above embodiments, Ti films are used as close-contact films. However, metal silicide films may be used as close-contact films. The close-contact films may be grown by CVD, evaporation, or the like other than sputtering.

In each of the above embodiments, Ru films are used as the metal films of the lower and upper electrodes, However, films of a metal in the platinum group, e.g., Pt, Ir, or the like, or a conductive oxide, e.g., RuO₂, IrO₂, or the like may be used as the metal films of the lower and upper electrodes. The metal films of the lower and upper electrodes may be grown by CVD, evaporation, or the like other than sputtering.

In the above embodiments, a PZT film having a specific inductive capacity ranging from 300 to 1200 is used as a thin ferroelectrics film serving as a capacitor film. However, the thin ferroelectrics film serving as the capacitor film is not limited to the PZT film, but may be a film of (Pb, La)(Zr, Ti)O₃ having a specific inductive capacity ranging from 350 to 1100, SrBi₂Ta₂O₃, or a perovskite thin ferroelectrics film. The present invention is also applicable to a high-dielectric capacitor element using a high-dielectric film such as of tantalum oxide Ta₂O₅, BST((Ba, Sr)TiO₃), or the like as a capacitor film.

In each of the above embodiments, a method of manufacturing a ferroelectric memory, which has the steps of forming a multilayer metal interconnection structure and then forming a capacitor structure, has been described by way of example. However, the present invention is not limited to a semiconductor device fabricated by such a method, but can be carried out to fabricate any semiconductor devices having a capacitor structure including a lower electrode, a capacitor film, and an upper electrode. A thin ferroelectrics film serving as a capacitor film may be grown by a chemical film growth process such as a CVD process, a sol-gel process, or the like. If the present invention is not applied to the fabrication of a semiconductor device having a capacitor structure on a multilayer metal interconnection structure, then a thin ferroelectrics film serving as a capacitor film may be grown by sputtering.

According to the present invention, as described above, since a laminated structure made up of a capacitor film, a lower electrode, and an insulating film, and a capacitor film, a barrier film, and an insulating film is not present on the outer circumferential edge of a wafer when a capacitor film is formed, the capacitor film and the lower electrode are prevented from being peeled off, no contamination is caused in the fabrication process, and the yield of products is improved.

According to the present invention, the process of fabricating ordinary semiconductor integrated circuits can be used up to the stage where active elements and metal interconnection structures are formed on a semiconductor substrate. When a capacitor structure is produced, a capacitor film is prevented from being peeled off, and a good dielectric film can be produced at a relatively low temperature, so that device reliability and product yield can be improved.

While preferred embodiments of the present invention have been described using specific terms, such description is for illustrative purposes only, and it is to be understood that changes and variations may be made without departing from the spirit or scope of the appended claims.

What is claimed is:

1. A method of manufacturing a semiconductor device having a capacitor element, comprising the steps of:
forming a laminated film made up of a first close-contact film, a barrier film, and a second close-contact film arranged successively in the order named, on a wafer;
forming a metal film serving as a lower electrode on said laminated film in a region radially inward, with respect to the wafer, of an outer edge of said laminated film;
etching away a portion of said laminated film which is exposed radially outwardly, with respect to the wafer, of an outer edge of said metal film; and
forming a capacitor film in covering relation to said metal film.

2. A method of manufacturing a semiconductor device having a capacitor element, comprising the steps of:
forming a laminated film made up of a first close-contact film, a barrier film, and a second close-contact film arranged successively in the order named, on a wafer, by forming said first close-contact film, forming said barrier film on said first close-contact film in a region radially inward, with respect to the wafer, of an outer edge of said first close-contact film, and then forming said second close-contact film in an area wider than said barrier film in covering relation to said barrier film;
forming a metal film serving as a lower electrode on said second close-contact film in a region radially inward, with respect to the wafer, of outer edges of said first and second close-contact films; and
forming a capacitor film in covering relation to said metal film.

3. A method according to claim 2, wherein said metal film extends to a region radially outward, with respect to the wafer, of an outer edge of said barrier film.

4. A method of manufacturing a semiconductor device by fabricating a capacitor structure made up of a lower electrode, a capacitor film, and an upper electrode, comprising the steps of:
forming a laminated film made up of a first close-contact film, a barrier film, and a second close-contact film arranged successively in the order named, on a wafer;
forming a metal film serving as said lower electrode on said laminated film radially inwardly, with respect to the wafer, of an outer edge of said laminated film;
etching a portion of said laminated film which is exposed radially outwardly, with respect to the wafer, from an outer edge of said metal film, using said metal film as a mask; and
forming a capacitor film on said metal film.

5. A method of manufacturing a semiconductor device by fabricating a capacitor structure made up of a lower electrode, a capacitor film, and an upper electrode, comprising the steps of:
forming a laminated film made up of a first close-contact film, a barrier film, and a second close-contact film arranged successively in the order named, on a wafer;
forming a metal film serving as said lower electrode on said laminated film radially inwardly, with respect to the wafer, of an outer edge of said laminated film;
providing a resist on said metal film;
etching a portion of said laminated film which is exposed radially outwardly, with respect to the wafer, from an outer edge of said metal film on an outer circumferential edge of the wafer, using said metal film as a mask; and
after removing said resist from said metal film, forming said capacitor film in covering relation to said metal film.

6. A method according to claim 5, further comprising the step of:
after coating said metal film with said resist, adjusting an outer edge of said resist so as to be positioned radially inwardly, with respect to the wafer, of the outer edge of said metal film.

7. A method of manufacturing a semiconductor device by fabricating a capacitor structure made up of a lower electrode, a capacitor film, and an upper electrode, comprising the steps of:
forming a laminated film made up of a first close-contact film, a barrier film, and a second close-contact film arranged successively in the order named, on a wafer;
forming a metal film serving as said lower electrode on said laminated film;
said metal film and said barrier film having respective outer edges positioned, successively in the order named, radially inwardly, with respect to the wafer, of outer edges of said first and second close-contact films; and
forming said capacitor film in covering relation to said metal film.

8. A method of manufacturing a semiconductor device by fabricating a capacitor structure made up of a lower electrode, a capacitor film, and an upper electrode, on a surface of an insulating film in an uppermost layer of a wafer with active elements formed on a surface thereof and a metal interconnection structure having a predetermined number of layers and disposed in an upper layer on the wafer, said method comprising the steps of:
forming a laminated film made up of a first close-contact film, a barrier film, and a second close-contact film arranged successively in the order named, on said insulating film;
forming a metal film serving as said lower electrode on said laminated film in a region radially inward, with respect to the wafer, of an outer edge of said laminated film;
after coating said metal film with a resist, adjusting an outer edge of said resist so as to be positioned radially inwardly, with respect to the wafer, of an outer edge of said metal film;
etching a portion of said laminated film which is exposed radially outwardly, with respect to the wafer, from the outer edge of said metal film on an outer circumferential edge of the wafer, using said metal film as a mask; and
after removing said resist from said metal film, forming said capacitor film in covering relation to said metal film on the surface of the wafer.

9. A method of manufacturing a semiconductor device by fabricating a capacitor structure made up of a lower electrode, a capacitor film, and an upper electrode, on a surface of an insulating film in an uppermost layer of a wafer with active elements formed on a surface thereof and a metal interconnection structure having a predetermined number of layers and disposed in an upper layer on the wafer, said method comprising the steps of:
forming a laminated film made up of a first close-contact film, a barrier film, and a second close-contact film arranged successively in the order named, on said insulating film;
forming a metal film serving as the lower electrode on said laminated film in a region radially inward, with respect to the wafer, of an outer edge of said laminated film;
said first and second close-contact films, said metal film, and said barrier film having respective outer edges positioned successively in the order named radially inwardly, with respect to the wafer, on an outer circumferential edge of the wafer; and
forming said capacitor film in an area wider than said metal film in covering relation to said metal film.

10. A method according to claim 1, wherein said capacitor film comprises a thin ferroelectrics film or a thin high-dielectric film.

11. A method according to claim 1, wherein said capacitor film comprises a thin film of either one of Pb(Zr, Ti)O₃, (Pb, La)(Zr, Ti)O₃, and SrBi₂Ta₂O₃.

12. A method according to claim 1, wherein said metal film as said lower electrode is made of a metal in the platinum group or an oxide of a metal in the platinum group.

13. A method according to claim 1, wherein said metal film as the lower electrode is made of at least one of Ru, Pt, Ir, RuO₂, and IrO₂.

14. A method according to claim 1, wherein each of said first and second close-contact films comprises a conductive film, and said barrier film comprises a conductive nitride film.

15. A method according to claim 1, wherein each of said first and second close-contact films is made of Ti, and said barrier film is made of TiN.

16. A method according to claim 1, wherein each of said first and second close-contact films is made of Ti, Ta, or metal silicide, and said barrier film is made of TiN or WN.

17. A method according to claim 1, wherein said capacitor film is grown by chemical vapor deposition.

18. A method according to claim 1, wherein said capacitor film is grown by sputtering.

19. A method according to claim 1, wherein when said close-contact films, said metal film, and said barrier film are grown, the inside diameter of a clamp ring of a film growth apparatus for clamping the wafer on a stage is changed to position the respective outer edges of said close-contact films, said metal film, and said barrier film successively in the order named radially inwardly with respect to the wafer.

20. A method of manufacturing a semiconductor device having, on a semiconductor substrate, a capacitor element having a dielectric film and lower and upper electrodes sandwiching said dielectric film therebetween, and a barrier layer disposed between said capacitor element and an insulating film beneath said lower electrode, said semiconductor device being electrically connected to a base layer by a conductive member disposed in said insulating film, said barrier layer having at least three films including a first metal film, a metal nitride film, and a second metal film successively from below, said method comprising the steps of:
forming a laminated film made up of said first metal film serving as said barrier layer, said metal nitride film, and said second metal film successively on said insulating film on a wafer;
forming a metal film serving as said lower electrode on said laminated film in a region radially inward, with respect to the wafer, of an outer edge of said laminated film;
etching away a portion of said laminated film which is exposed radially outwardly, with respect to the wafer, from an outer edge of said metal film as said lower electrode; and
forming said dielectric film in covering relation to said metal film as the lower electrode.

21. A method of manufacturing a semiconductor device having, on a semiconductor substrate, a capacitor element having a dielectric film and lower and upper electrodes sandwiching said dielectric film therebetween, and a barrier layer disposed between said capacitor element and an insulating film beneath said lower electrode, said semiconductor device being electrically connected to a base layer by a conductive member disposed in said insulating film, said barrier layer having at least three films including a first metal film, a metal nitride film, and a second metal film successively from below, said method comprising the steps of:
forming a laminated film made up of said first metal film serving as said barrier layer, said metal nitride film, and said second metal film successively on said insulating film on a wafer, by forming said first close-contact film, forming said metal nitride film on said first close-contact film in a region radially inward, with respect to the wafer, of an outer edge of said first close-contact film, and then forming said second close-contact film in an area wider than said metal nitride film in covering relation to said metal nitride film;
forming a metal film serving as the lower electrode on said second metal film in a region radially inward, with respect to the wafer, of outer edges of said first and second metal films; and
forming said dielectric film in covering relation to said metal film as the lower electrode.

22. A method according to claim 21, wherein said metal film as the lower electrode extends to a region radially outward, with respect to the wafer, of an outer edge of said metal nitride film.

23. A method according to claim 20, wherein said metal nitride film is made of a nitride of a metal element of said first metal film or said second metal film.

24. A method according to claim 20, wherein said lower electrode is made of at least one of elements in the platinum group including Ru and Ir and conductive oxides of elements in the platinum group.

25. A method according to claim 20, wherein a combination of the metal of said first metal film and the metal of said second metal film comprises at least one of:
Ti and Ti;
Ti and Ta;
Ta and Ti; and
Ta and Ta.

26. A method according to claim 20, wherein said dielectric film is grown by chemical vapor deposition.

27. A method according to claim 20, wherein said dielectric film is grown by a sputtering process or a sol-gel process.

28. A method according to claim 21, wherein when said first and second metal films, said metal film as said lower electrode, and said metal nitride film are grown, the inside diameter of a clamp ring of a film growth apparatus for clamping the wafer on a stage is changed to position the respective outer edges of said first and second metal films, said metal film as the lower electrode, and said metal nitride film successively in the order named radially inwardly with respect to the wafer.
